(19) United States
(12) Patent Application Publication
(10) Pub. No.: US 2026/0031118 A1
(43) Pub. Date: Jan. 29, 2026

(54) METHOD AND DEVICE FOR PARALLEL ANALOG IN-MEMORY COMPUTING

(71) Applicant: NANJING UNIVERSITY, Jiangsu (CN)

(72) Inventors: Feng MIAO, Jiangsu (CN); Cong WANG, Jiangsu (CN); Shijun LIANG, Jiangsu (CN); Wei Wei, Jiangsu (CN)

(73) Assignee: NANJING UNIVERSITY, Jiangsu (CN)

(21) Appl. No.: 18/895,326

(22) Filed: Sep. 24, 2024

(30) Foreign Application Priority Data
Jul. 29, 2024 (CN) 202411020765.1

(51) Int. Cl. G11C 7/16; G11C 7/10; H03M 1/36

(52) U.S. Cl. CPC G11C 7/16; G11C 7/1006; H03M 1/366

(57) ABSTRACT

A method for parallel analog in-memory computing is provided. The method includes the following steps: inputting an analog current signal; replicating the analog current signal to form a corresponding replicated current signal, and performing weighted processing of all the replicated current signals to obtain a corresponding set of modulated current signals; and performing weighted accumulated operation of the set of modulated current signals according to Kirchhoff's current law to obtain an output current signal. In the present disclosure, input, processing and output of signals are performed in a pure current domain, and precise replication and output of current signals are achieved, thereby ensuring the output current precision even under the condition of a high line resistance.

### CROSS-REFERENCE TO RELATED APPLICATION

This application claims the priority benefit of China application no. 202411020765.1, filed on Jul. 29, 2024. The entirety of the above-mentioned patent application is hereby incorporated by reference herein and made a part of this specification.

### TECHNICAL FIELD

The present disclosure relates to the technical field of integrated circuits, and particularly relates to a method and device for parallel analog in-memory computing.

### DESCRIPTION OF RELATED ART

In today's information age, applications of computer vision, autonomous driving and the like all require computing systems to analyze and process a large number of input signals in real time in complex and changeable real-world environments. To meet the requirement, the computing systems need to be capable of performing high-speed and accurate weighted calculations of received high-precision information according to certain rules and requirements and outputting precise computing results. With the arrival of a big data era, an increasing computational load has imposed increasingly rigorous requirements for scales and precisions of computing chips. Moreover, variability of application environments necessitates high robustness of the computing systems to achieve applications of the computing systems in various extreme usage scenarios.

At present, core chips of mainstream computing systems are based on complementary metal-oxide-semiconductor (CMOS) technology, and transistors serve as basic units. Main components of a chip include an analog-to-digital/digital-to-analog converter, a memory unit (such as a classic 6T-SRAM structure), a processing unit (a combinational logic circuit), and other circuit modules. During actual operation, an external sensor converts received environmental information into an electrical analogue signal, then an analog-to-digital converter of a computing chip converts the information into a digital signal, and finally the signal is stored in the memory unit via a communication line. In the memory unit, the chip represents data “0” and “1” respectively through high and low levels, and the memory unit implements writing and reading of the high and low levels through a memory composed of the transistors. One memory unit is capable of representing data with a precision of only 1 bit. During computation, the chip reads digital information from the memory unit via a data line, and a final computational result is obtained after logic computing and processing in the combinational logic circuit based on the transistors. In practical applications, to meet the requirement for processing complex multi-channel signals, parallel processing and analysis of different information are required. According to solutions in the prior art, a matrix switch composed of relays or CMOS transmission gates is mainly employed to select information, and serial processing of the information is based on a global clock signal.

This category of computing chips adopts a Von Neumann architecture that separates storage and computation, which results in transmission of massive data between the processing unit and the memory unit during a computing process. Energy losses and bandwidth limitations from the transmission of massive data limit enhancement of computing performance. Moreover, CMOS transistors as core hardware of the computing chips will experience output characteristic curve drift due to changes in an ambient temperature, thereby leading to degradation of computational precision.

Analog computing chips belong to another category of chips that offer solutions of current domain computing based on emerging elements, and include field-effect transistors, non-volatile memory elements, and other units (such as a 1T1R structure). In such chips, conventional memory units and processing units are no longer distinguished, and information is stored in crossbar arrays in the form of analog physical quantities (such as conductance values). According to conventional current domain computing schemes, during computation, environmental information received by a sensor is converted into an analog current signal, and then the analog current signal is converted into an analog voltage signal via a current to voltage converter, and fed into a crossbar array as an input vector. When an analog voltage is applied to a resistor, a series of analog current signals are output according to Ohm's law, and matrix-vector multiplication calculations are performed in situ at output nodes according to Kirchhoff's law. A sign (positive or negative) and amplitude of an analog voltage signal represent the sign and magnitude of an element in the input vector, and a resistance value stored in the crossbar array represents a matrix element. Generally, to represent a negative element value, a conductance difference between two adjacent memory elements is used to represent an element. For the arrays, a computing paradigm of voltage domain input to current domain output is adopted as a whole.

According to conventional current-domain computing methods, when a scale of a chip array is continuously expanded, a line resistance between units also increases. Since data is usually represented by a resistance state of a memory element and input according to a voltage, an increase in the line resistance inevitably leads to additional circuit voltage division and partial loss of an input voltage caused by the line resistance, such that output analog current decreases, computational precision degrades, and system power consumption increases. Moreover, the resistance of a memory element may drift with changes in the ambient temperature. To ensure the computational precision, the number of multi-states of the memory element must be minimized, thereby further limiting the computing performance of the array.

According to a computing system in the prior art, analog domain signals are processed via a digital circuit. Firstly, due to incompatibility between a digital signal and an analog signal, the analog signal has to be converted into a discrete digital signal for further processing. Problems of efficiency and power consumption are likely to occur in a process of analog-to-digital or digital-to-analog signal conversion. The conventional chips perform the serial processing of information based on the clock signals and fail in massive parallel computing of data, thereby fundamentally restricting computational efficiency. Secondly, according to the conventional current domain computing schemes, a voltage amplitude represents an input quantity, and a conductance value represents a weight value. When the scale of a computing chip array is expanded, the line resistance thereof significantly increases, which results in inevitable degradation in the precision of output current, as well as precision loss and more system power consumption. Therefore, further enhancement of the conventional current domain computing schemes is hardly achieved due to limitation of scalability by computing principles. Thirdly, the computing systems are usually affected and restricted by different environmental factors (such as the ambient temperature and humidity) and usage scenarios (such as power consumption limitations of application in mobile phones, automobiles and other equipment). The transistors in the conventional chips may experience the output characteristic curve drift with changes in the ambient temperature, which will lead to saturation distortion, increased output errors, and degrading computational precision. Therefore, in the prior art, the computing systems usually cannot operate directly under extreme conditions. Further, the computational precision of the computing systems has to be sacrificed to some extent under the conditions of fluctuating ambient temperatures to meet requirements for robustness of the systems.

### SUMMARY

Invention objective: a first objective of the present disclosure is to provide a method for parallel current-domain analog in-memory computing that is capable of achieving ultra-large-scale integration of hardware and active computational precision adjustment. A second objective of the present disclosure is to provide a device for the method for parallel current-domain analog in-memory computing.

Technical solution: the method for parallel analog in-memory computing described in the present disclosure includes the following steps:
inputting an analog current signal;
replicating the analog current signal to form a corresponding replicated current signal, and performing weighted processing of all the replicated current signals to obtain a corresponding set of modulated current signals; and
performing weighted accumulated operation of the set of modulated current signals according to Kirchhoff's current law to obtain an output current signal.

Further, the analog current signal is replicated through a current replication circuit to form a corresponding replicated current signal. Preferably, the current replication circuit is a current mirror circuit.

Further, the weighted processing of the replicated current signal is detailed as follows:

Weight assignment is achieved through a switch module; when a switching element is in a low-resistance state, an output modulated current signal equals an input current signal, representing that the current signal is assigned with a weight of “1”; and when the switching element is in a high-resistance state, the output modulated current signal is far less than the input current signal, representing that the current signal is assigned with a weight of “0”. When the switching element is in the low-resistance state, an output current precisely corresponds to an input current; when the switching element is in the high-resistance state, the output current of the switching element is limited by a resistance of the switching element, and the output current is saturated after exceeding a certain threshold and no longer increases with an increase of the input current. Therefore, by controlling a resistance state of the switching element and a magnitude of the input current, stable output of high and low current bits of a single-bit unit can be achieved, and a switching ratio of high and low current levels can be precisely controlled by adjusting the resistance state of the switching element and the magnitude of the input current.

The device for the method for parallel analog in-memory computing of the present disclosure includes:
single-bit units, configured for replicating and weighted processing of analog current signals to obtain a set of modulated current signals; and
of modulated current signals according to Kirchhoff's current law to obtain an output current signal.

Further, each of the single-bit units includes a replication module and a switch module;
the replication module is configured for replicating the analog current signal and outputting the replicated current signal at a ratio of 1:1 or any other fixed ratio; and
the switch module is configured for performing the weighted processing of the replicated current signal.

Further, the replication module is a current mirror circuit that replicates the input current at a ratio of 1:1, and includes a first transistor M₁ and a second transistor M₂, where a gate electrode of the M₁ and a gate electrode of the M₂ are short-circuited, and a drain electrode and the gate electrode of the M₂ are short-circuited. An analog current signal I₁ is input from the drain electrode of the M₂, and output characteristics of the M₁ and the M₂ are as follows:

$${I}_{1} = \frac{1}{2} {μ}_{n} {{C}_{o x} ( \frac{W}{L} )}_{1} {( {V}_{1} - {V}_{t h} )}^{2}$$

$${I}_{2} = \frac{1}{2} {μ}_{n} {{C}_{o x} ( \frac{W}{L} )}_{2} {( {V}_{2} - {V}_{t h} )}^{2}$$

$${V}_{2} = {V}_{1}$$

$${I}_{2} = \frac{{( \frac{W}{L} )}_{2}}{{( \frac{W}{L} )}_{1}} {I}_{1}$$

$$When \frac{{( \frac{W}{L} )}_{2}}{{( \frac{W}{L} )}_{1}} = 1 ,$$

$${I}_{2} = {I}_{1}$$

where, μₙ is an electron mobility, Cₒₓ is a gate oxide capacitance of an MOS element, V₁ is a voltage drop at the gate electrode of the transistor M₁ caused by an input current I₁, Vₜₕ is a threshold voltage, and V₂ is a gate voltage of the gate electrode of the second transistor M₂. Temperature-dependent parameters un and Vₜₕ are eliminated, such that an output-to-input ratio of the replication module is solely related to a channel width-to-length ratio of the M₁ or the M₂, such that the output current is a result of exact copy of the input current. When the channel width-to-length ratio of the M₁ or the M₂ is a fixed value, a ratio of the replicated current to the output current remains consistent with the channel width-to-length ratio.

Preferably, each of the switch modules includes a memristor or a non-volatile memory, and the non-volatile memory is one or more of MRAM, PCM and FLASH. The switch module in the single-bit unit is configured for allocating weights of “0” and “1”, and different memory elements are selected to achieve this function.

Further, the weighted module performs weighted summation of output modulated current signals from n switch modules respectively with 2ⁱ as weighted values, where n is an integer and i is an integer ranging from 0 to n−1, to obtain an output current signal with a n-bit precision.

Further, an electronic element of the weighted module is one or more of the memristor, the MRAM, the PCM and the FLASH.

Further, the replication modules and the switch modules form a crossbar array.

Beneficial effects: compared to the prior art, the present disclosure has the following significant advantages: 1. In the present disclosure, analog current signals are directly processed, both input signals and output signals are analog current signals, and weighted calculation of analog signals is performed in a pure current domain, such that efficient parallel processing of image information acquired by sensors is achieved. 2. In the present disclosure, the replication modules and the switch modules form the single-bit units, input current signals are replicated, weighted and processed, input, processing and output of signals from the entire single-bit unit are performed in the pure current domain, and precise replication and output of current signals are achieved, thereby ensuring the output current precision even under the condition of a high line resistance, and avoiding the precision degradation of output current caused by a line resistance according to conventional current domain computing schemes. 3. The present disclosure significantly reduces negative impacts caused by non-ideal factors such as line resistance voltage division when a device scale is expanded, thereby having more potential for integration and scalability. 4. The present disclosure achieves active adjustment of the computational precision through the weighted module, greatly eliminates the impacts of memory element temperature drift through a symmetrical structure when an ambient temperature changes, and enables higher precision and robustness of computing even under the condition of extreme temperature variations.

### BRIEF DESCRIPTION OF THE DRAWINGS

FIG. 1 is a flowchart of an example of the present disclosure.

FIG. 2 is a structural schematic diagram of a device for parallel analog in-memory computing of the present disclosure.

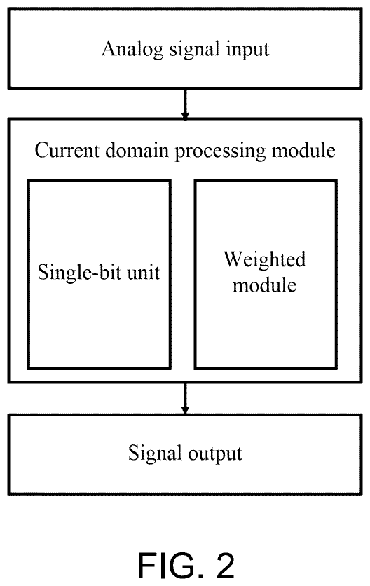

FIG. 3 is a structural schematic diagram of a replication module and a switch module of the present disclosure.

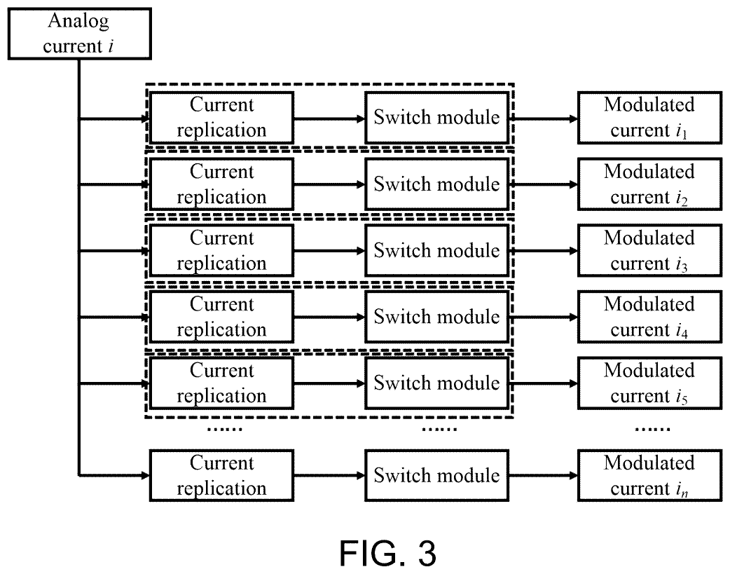

FIG. 4 is a structural schematic diagram of a weighted module of the present disclosure.

FIG. 5 is a structural schematic diagram of a replication module and a switch module involved in an embodiment of the present disclosure.

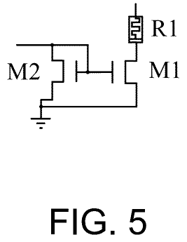

FIG. 6 is a structural schematic diagram of a replication module and a switch module involved in an embodiment of the present disclosure.

### DESCRIPTION OF THE EMBODIMENTS

The present disclosure will be further described below with reference to the accompanying drawings.

The method for parallel analog in-memory computing described in the present disclosure includes the following steps:
S1, inputting an analog current signal;
S2, replicating the analog current signal through a current replication circuit to form a corresponding replicated current signal, and performing weighted processing of all the replicated current signals to obtain a corresponding set of modulated current signals, where the weighted processing of the replicated current signal is detailed as follows:
weight assignment is achieved through a switch module; when a switching element is in a low-resistance state, an output modulated current signal equals an input current signal, representing that the current signal is assigned with a weight of “1”; and when the switching element is in a high-resistance state, the output modulated current signal is far less than the input current signal, representing that the current signal is assigned with a weight of “0”; when the switching element is in the low-resistance state, an output current precisely corresponds to an input current; when the switching element is in the high-resistance state, the output current of the switching element is limited by a resistance of the switching element, and the output current is saturated after exceeding a certain threshold and no longer increases with an increase of the input current; therefore, by controlling a resistance state of the switching element and a magnitude of the input current, stable output of high and low current bits of a single-bit unit can be achieved, and a switching ratio of high and low current levels can be precisely controlled by adjusting the resistance state of the switching element and the magnitude of the input current; and
S3, performing weighted accumulated operation of the set of modulated current signals according to Kirchhoff's current law to obtain an output current signal.

The device for the method for parallel analog in-memory computing of the present disclosure includes:
single-bit units, configured for replicating and weighted processing of analog current signals to obtain a set of modulated current signals, where each of the single-bit units includes a replication module and a switch module, where the replication module is configured for replicating the analog current signal and outputting the replicated current signal at a ratio of 1:1 or any other fixed ratio, and the switch module is configured for performing the weighted processing of the replicated current signal; and
weighted modules, configured for performing weighted accumulated operation of the set of modulated current signals according to Kirchhoff's current law to obtain an output current signal.

An output end of the replication module is connected to an input end of the switch module, and an output end of the switch module is connected to an input end of the weighted module.

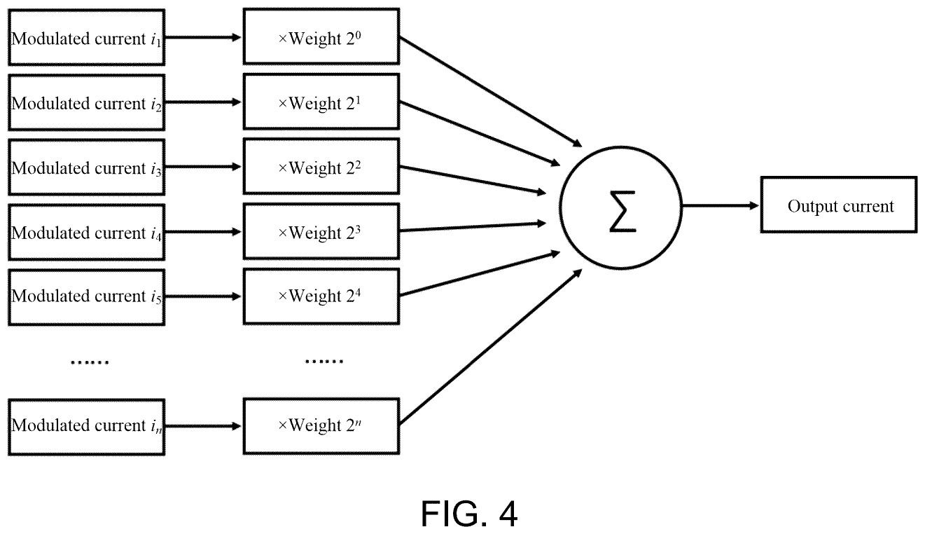

A function of matrix-vector multiplication of the present disclosure is implemented through the replication module and the switch module, as shown in FIG. 4. The replication module is configured for achieving precise replication and output of an input current; and the switch module is configured for weighting and output of a current.

Functions of the replication module are implemented through a CMOS circuit, and the replication modules with different structures and elements vary in circuit complexity, precision and robustness. Generally speaking, the replication module is based on a current mirror circuit structure, and alternatively, additional transistors and connections (such as cascode designs) can be added to achieve a higher impedance and a smaller amplitude of transistor swing, and alleviate the impact of channel width modulation effects, so as to enhance replication precision and circuit robustness. Alternatively, different electronic elements (such as a field-effect transistor, a bipolar junction transistor, and the like) can be used for circuit designs. Specific circuit designs and connections are intended to achieve current replication and output, different specific structures vary solely in costs and performance, and these variations do not change the core design concept of the present disclosure. In practical applications, different modules can be selected based on different actual needs in a targeted manner.

Generally speaking, the switch module is configured for allocating weights of “0” and “1”, which can be implemented by an element capable of binary weighting. This element can be a memristor, an MRAM, a PCM, a FLASH, a fixed resistor, a variable resistor, or any other mature electronic element with a non-volatile signal modulation function. Selection of these specific memory elements does not change the core design concept of the present disclosure.

In this example, the replication module is based on a CMOS current mirror circuit, and the switch module is based on a memristor, as shown in FIG. 4. The replication module includes a transistor M₁ and a transistor M₂. A gate electrode of the M₁ is connected to a gate electrode and a drain electrode of the M₂. In a signal input phase, current signals are input from the drain electrode of the M₂. Since the drain electrode and the gate electrode of the M₂ are short-circuited, and the M₂ continuously works in a saturation region, output characteristics of the M₁ and the M₂ can be expressed respectively as follows:

$${I}_{1} = \frac{1}{2} {μ}_{n} {C}_{o x} \frac{W}{L} {( {V}_{1} - {V}_{th} )}^{2} \qquad ( 1 )$$

$${V}_{1} = \sqrt{\frac{2 IL}{{μ}_{n} {C}_{o x} W}} + {V}_{th} \qquad ( 2 )$$

$${I}_{2} = \frac{1}{2} {μ}_{n} {C}_{o x} \frac{W}{L} {( {V}_{2} - {V}_{th} )}^{2} \qquad ( 3 )$$

$${I}_{2} = \frac{{( \frac{W}{L} )}_{2}}{{( \frac{W}{L} )}_{1}} {I}_{1} \qquad ( 4 )$$

In the equations, μₙ is an electron mobility, and Vₜₕ is a threshold voltage, both of which are temperature-dependent parameters; and Cₒₓ is a gate oxide capacitance of an MOS element. A voltage drop V₁ at the gate electrode of the transistor M₁ caused by an input current I₁ is shown in the equation (2). Because the gate electrodes of the M₁ and the M₂ are short-circuited, a gate voltage V₂ applied to the gate electrode of the M₂ is equal to V₁, and an output current I₂ is generated through its own transconductance (as shown in the equation (3)). The equations (1), (2), and (3) are combined to obtain an expression (4) of relation between the output current I₂ and the input current I₁. An output relationship between the M₁ and the M₂ is combined through an inverse function equation (2) of the equation (1), thereby eliminating the need of using the temperature-dependent parameters μₙ and Vₜₕ. An output-to-input ratio of the replication module is solely related to a channel width-to-length ratio of the M₁ or the M₂, such that the output current is a result of exact copy of the input current. When the channel width-to-length ratio of the M₁ or the M₂ is a fixed value, a ratio of the replicated current to the output current remains consistent with the channel width-to-length ratio.

The corresponding switch module is configured for controlling a weight of the output current and achieving a matrix-vector multiplication operation, and includes a switching element. When a switching element R₁ is in the low-resistance state, the output current of the R₁ precisely corresponds to the input current I₁; when the switching element R₁ is in the high-resistance state, the output current of the R₁ is limited by a resistance of the R₁, and the output current is saturated after exceeding a certain threshold and no longer increases with an increase of the input current I₁. Therefore, by adjusting the switching element R to an appropriate resistance state and selecting an appropriate input current, stable output of high and low current bits can be achieved, where a high current output corresponds to “1” and a low current output corresponds to “0”. The switching ratio of high and low current levels can be precisely controlled by adjusting the resistance state of the R₁ and the magnitude of the input current.

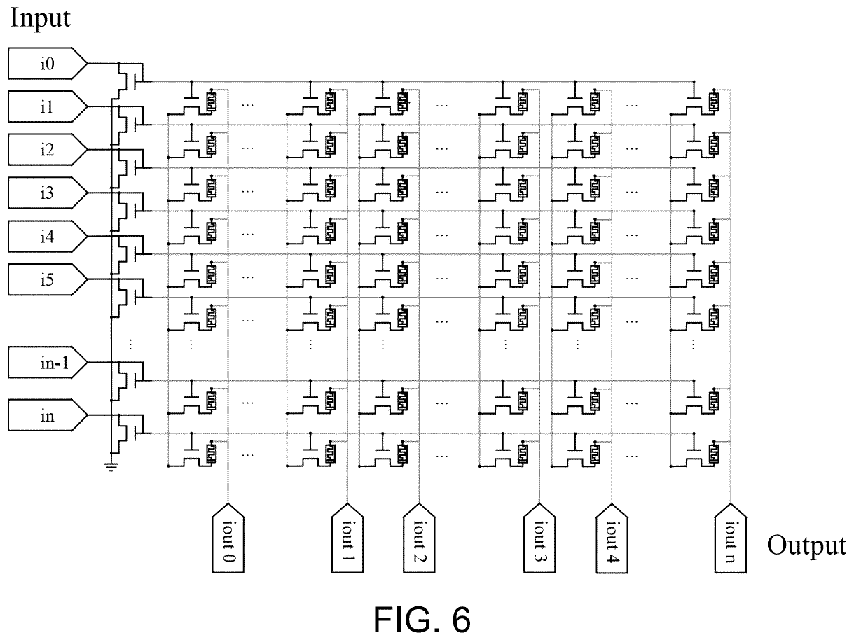

The replication modules and the switch modules, as parts of single-bit units, constitute a large-scale crossbar array, as shown in FIG. 6. For a device with n rows of input and m columns of output, all the replication modules form a n×1 array, and all the switch modules form an n×m array.

The weighted module is shown in FIG. 4, and the weighted module performs weighted summation of a series of single-bit current signals that have been processed by the replication modules and the switch modules, to obtain a higher-precision output result. A series of n current signals processed through the above modules are further assigned with different weights in the form of exponentially increasing powers of 2 (such as 1, 2, 4, 8, and the like), followed by further summation, to obtain an output result

$${i}_{out} = {\sum }_{i = 0}^{n} ( {2}^{i} * {i}_{i + 1} )$$

with an nbit precision. The weights corresponding to different items in the weighted module are represented by n storage elements with multi-state non-volatile signal modulation capabilities. Each of the storage elements can be the memristor, the MRAM, the PCM, the FLASH, the fixed resistor, the variable resistor, or any other mature electronic element with the non-volatile signal modulation function. Selection of these specific memory elements does not change the core design concept of the present disclosure. A series of modulated current signals can be directly subjected to current summation according to Kirchhoff's law, or summation thereof can be implemented through an adder circuit and the like. A specific design can only affect circuit precision, stability, cost and the like, and does not compromise the core spirit of the present disclosure. Each of the storage elements is capable of storing a weight value w proportional to the n^{th} power of 2, meaning that conductance values of two adjacent storage elements vary by a factor of 2. When an i^{th} input signal iᵢ flows into the weighted module, an analog signal 2ⁱ⁻¹*iᵢ is output, and then n analog signals are summed to obtain a final output result

$${i}_{out} = {\sum }_{i = 0}^{n} ( {2}^{i} * {i}_{i + 1} ) .$$

As the number n of superposed signal paths increases, an output precision also increases; and the entire device is capable of achieving output results of different precisions by modulating a size of n.

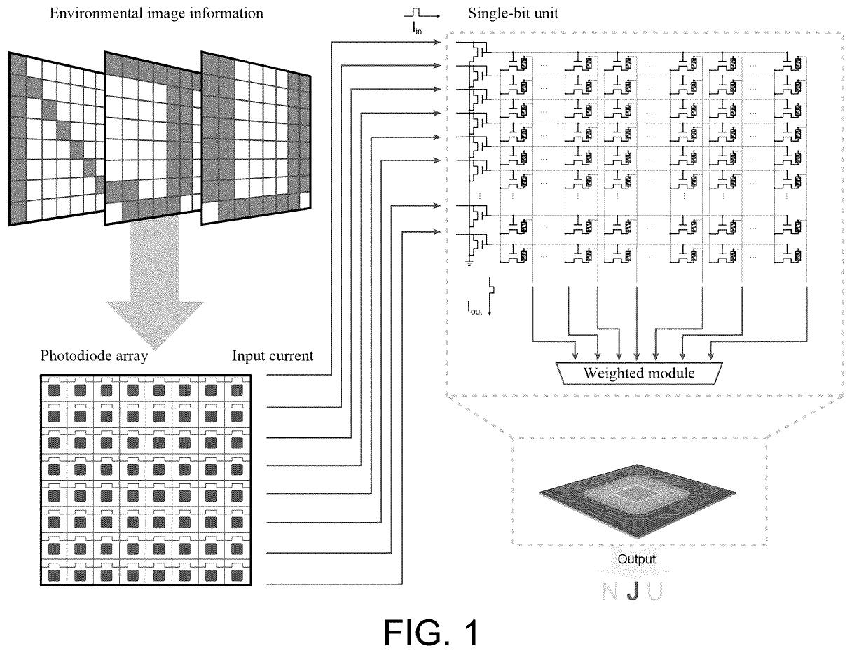

In this example, the input current signals of the device are based on current signals from image sensors such as cameras or photodiode arrays. As shown in FIG. 1, the replication module and the weighted module of the present disclosure are connected to a photodiode array (for signal input) and a display (for output display) respectively. The present disclosure is used to monitor image information from replication environments and achieve real-time analysis and output.

In this example, a trained neural network weight matrix is input into the switch module in a binary format. When an image sensor works, the photodiode array receives information from real environments and converts the information into a photocurrent vector, and the photocurrent vector as original current information is directly input into an array composed of the replication modules and the switch modules of the present disclosure. Any input current information, after being processed by the array and integrated by the weighted module, becomes an output current vector signal with an adjustable precision. These output results further act on a back-end display and a back-end processor. In this example, after processing of input signals through the device of the present disclosure, real-time recognition results can be displayed directly on the back-end display, and recognition and detection of environmental information can be achieved.

The present disclosure is capable of directly performing parallel weighted summation of a series of input analog current signals and outputting high-precision and controllable results. The present disclosure processes information in a pure current domain, which, in principle, overcomes the defects of precision loss due to line resistance voltage division that further limits an integration scale according to conventional schemes. Therefore, the present disclosure is capable of significantly reducing the limitations on an array scale according to original schemes, and constructing a larger-scale in-memory computing hardware array with higher performance and integration capacity. Further, high symmetry of the modules designed for the device of the present disclosure, combined with the adjustable weighted modules, allows for precision outputs suitable for a wide temperature range. Tests have shown that in an example with the current mirror circuit and the memristor as core elements, an output precision of no less than 6 bit can be achieved in an ambient temperature range of 100 K to 500 K. The device of the present disclosure demonstrates higher robustness and precision and achieves stable and high-performance operation in environments with extreme temperature variations, such as polar observation stations and space environments.

Further, the present disclosure directly processes analog current signals output by sensors, eliminates the need of current-to-voltage conversion and analog-to-digital/digital-to-analog conversion, reduces complexity and additional energy consumption of the device, and increases a computational speed. The present disclosure has low complexity and cost, and significant potential and advantages for commercial applications.

What is claimed is:

1. A method for parallel analog in-memory computing, comprising the following steps:
inputting an analog current signal;
replicating the analog current signal to form a corresponding replicated current signal, and performing weighted processing of all replicated current signals to obtain a corresponding set of modulated current signals; and
performing weighted accumulated operation of a set of modulated current signals according to Kirchhoff's current law to obtain an output current signal.

2. The method for parallel analog in-memory computing according to claim 1, wherein the analog current signal is replicated through a current replication circuit to form the corresponding replicated current signal.

3. The method for parallel analog in-memory computing according to claim 2, wherein the weighted processing of all replicated current signals is detailed as follows:
performing weight assignment through a switch module, wherein the switch module comprises a switching element;
wherein when the switching element is in a low-resistance state, an output modulated current signal equals an input current signal, representing that the input current signal is assigned with a weight of “1”; and
wherein when the switching element is in a high-resistance state, the output modulated current signal is far less than the input current signal, representing that the input current signal is assigned with a weight of “0”.

4. A device using the method for parallel analog in-memory computing according to claim 1, comprising:
single-bit units, configured for replicating and weighted processing of analog current signals to obtain a set of modulated current signals; and
weighted modules, configured for performing weighted accumulated operation of the set of modulated current signals according to Kirchhoff's current law to obtain an output current signal.

5. The device according to claim 4, wherein each of the single-bit units comprises a replication module and a switch module;
the replication module is configured for replicating the analog current signal and outputting the replicated current signal of a fixed size; and
the switch module is configured for performing the weighted processing of the replicated current signal.

6. The device according to claim 5, wherein the replication module is a current mirror circuit that replicates the input current at a ratio of 1:1 or any other fixed ratio.

7. The device according to claim 5, wherein the switch module comprises a memristor or a non-volatile memory, and the non-volatile memory is one or more of MRAM, PCM and FLASH.

8. The device according to claim 4, wherein each of the weighted modules performs weighted summation of output modulated current signals from n switch modules respectively with 2ⁱ as weighted values, where n is an integer and i is an integer ranging from 0 to n−1, to obtain an output current signal with an n-bit precision.

9. The device according to claim 8, wherein an electronic element of each of the weighted modules is one or more of the memristor, the MRAM, the PCM and the FLASH.

10. The device according to claim 5, wherein replication modules and switch modules included in the single-bit units form a crossbar array.
